(19) United States
(12) Patent Application Publication
(10) Pub. No.: US 2026/0247543 A1
(43) Pub. Date: Aug. 20, 2026

(54) CIRCUIT BOARD, BATTERY PACK, AND METHOD OF MANUFACTURING CIRCUIT BOARD

(71) Applicant: MURATA MANUFACTURING CO., LTD., Kyoto (JP)

(72) Inventor: Hideyasu TAKATSUJI, Kyoto (JP)

(21) Appl. No.: 19/640,872

(22) Filed: Apr. 7, 2026

Related U.S. Application Data
(63) Continuation of application No. PCT/JP2025/019217, filed on May 28, 2025.

(30) Foreign Application Priority Data
Aug. 9, 2024 (JP) 2024-134575

(51) Int. Cl. H05K 3/28; H05K 1/181; H05K 3/303; H01M 50/284

(52) U.S. Cl. CPC H05K 3/284; H05K 1/181; H05K 3/303; H01M 50/284; H05K 2203/1316

(57) ABSTRACT

A circuit board includes a wiring board, a plurality of electronic components, and a resin part. The wiring board includes a major surface. The electronic components are mounted on the major surface. The resin part is a single, continuous part provided in contact with only a part of the major surface and covering the electronic components. The major surface of the wiring board includes a covered region and an uncovered region. The covered region is a single, continuous region covered with the resin part. The uncovered region is not covered with the resin part. The resin part includes an end part in contact with a non-mounting region, of the major surface, on which the electronic components are not mounted.

### CROSS REFERENCE TO RELATED APPLICATIONS

The present application is a continuation of International Application No. PCT/JP2025/019217, filed on May 28, 2025, which claims priority to Japanese Patent Application No. 2024-134575, filed on August 9, 2024, the entire contents of which are incorporated herein by reference.

### BACKGROUND

The present technology relates to a circuit board, a battery pack, and a method of manufacturing a circuit board.

A battery pack is provided with a circuit board that controls charging and discharging of a plurality of batteries in the battery pack.

### SUMMARY

The present technology relates to a circuit board, a battery pack, and a method of manufacturing a circuit board.

An electronic component such as an IC mounted on a circuit board may be covered with a waterproof resin in order to prevent deterioration due to moisture contained in an outside air or water exposure. Such a waterproof resin is formed by, for example, in a manufacturing process, sandwiching the circuit board with molds, plasticizing a solid resin pellet in a melting furnace and converting the solid resin pellet into liquid resin, injecting the liquid resin into the molds through a gate, and curing the liquid resin in the molds by cooling. When the waterproof resin is formed by such molding, the waterproof resin can have a burr or a void. If the waterproof resin has a burr or a void, when the electronic component is disposed at a location with the burr or the void, a waterproof property can decrease due to the burr or the void. Provided is a circuit board, a battery pack, and a method of manufacturing a circuit board that each make it possible to suppress a decrease in waterproof property caused by a burr or a void.

A circuit board according to a first embodiment of the present technology includes a wiring board, a plurality of electronic components, and a resin part. The wiring board includes a first major surface. The electronic components are mounted on the first major surface. The resin part is a single, continuous part provided in contact with only a part of the first major surface and covering the electronic components. The first major surface includes a covered region and an uncovered region. The covered region is a single, continuous region covered with the resin part. The uncovered region is not covered with the resin part. The resin part includes an end part in contact with a non-mounting region, of the first major surface, on which the electronic components are not mounted.

A battery pack according to a second embodiment of the present technology includes a circuit board that controls charging and discharging of one or more batteries. The circuit board includes a wiring board, a plurality of electronic components, and a resin part. The wiring board includes a first major surface. The electronic components are mounted on the first major surface. The resin part is a single, continuous part provided in contact with only a part of the first major surface and covering the electronic components. The first major surface includes a covered region and an uncovered region. The covered region is a single, continuous region covered with the resin part. The uncovered region is not covered with the resin part. The resin part includes an end part in contact with a non-mounting region, of the first major surface, on which the electronic components are not mounted.

A method of manufacturing a circuit board according to a third embodiment of the present technology is a method of manufacturing a circuit board including a wiring board, a plurality of electronic components, and a resin part. The wiring board includes a first major surface. The electronic components are mounted on the first major surface. The resin part is a single, continuous part provided in contact with only a part of the first major surface and covering the electronic components. The method of manufacturing the circuit board includes the following three processes.
(1) Stacking a mold including a recessed part, on the wiring board, and feeding an uncured resin into the recessed part, the wiring board including the first major surface on which the electronic components are mounted, the recessed part being a single, continuous part positioned to be opposed to a covering target region, the covering target region being a single, continuous region that is a part of the first major surface and includes the electronic components.
(2) Forming the resin part by cooling and solidifying, in the mold, the uncured resin fed into the recessed part.
(3) Removing the mold from the wiring board.

Here, the recessed part of the mold has an end part that is positioned to be opposed to a non-mounting region, of the first major surface, on which the electronic components are not mounted, when the mold is stacked on the wiring board.

In each of the circuit board according to the first embodiment of the present technology and the battery pack according to the second embodiment of the present technology, the resin part that is the single, continuous part covering the electronic components is provided with the end part in contact with the non-mounting region, of the first major surface of the wiring board, on which the electronic components are not mounted. For example, in a process of manufacturing the circuit board, when the wiring board is sandwiched by molds and an uncured resin as a raw material of the resin part is fed through a gate of the molds, this makes it possible to concentrate air bubbles generated in the uncured resin, in a part corresponding to the end part of the resin part. In the process of feeding the uncured resin as the raw material of the resin part through the gate of the molds, a pressure on the uncured resin can easily increase at the part corresponding to the end part of the resin part. Therefore, a burr generated in a process of curing the uncured resin can be generated easily at the part corresponding to the end part of the resin part. This makes it possible to limit a part in which the air bubble becomes a void as a result of resin curing or a part with a burr, to a part opposed to the non-mounting region on which the electronic components are not mounted. Accordingly, no electronic components are disposed at a part with a burr or a void. As a result, it is possible to suppress a decrease in waterproof property caused by a burr or a void.

In the method of manufacturing the circuit board according to the third embodiment of the present technology, to form the resin part, used is the mold including the recessed part having the end part that is positioned to be opposed to the non-mounting region, of the first major surface of the wiring board, on which the electronic components are not provided, when the mold is stacked on the wiring board. When stacking the mold including the recessed part that is the single, continuous part positioned to be opposed to the covering target region, which is the single, continuous region that is a part of the first major surface and includes the electronic components, on the wiring board including the first major surface on which the electronic components are mounted, and feeding the uncured resin into the recessed part, the above makes it possible to concentrate air bubbles generated in the uncured resin, in the end part of the recessed part. In the process of feeding the uncured resin as the raw material of the resin part through the gate of the mold, a pressure on the uncured resin can easily increase at the end part of the recessed part. Therefore, a burr generated in a process of curing the uncured resin can be generated easily at the end part of the recessed part. This makes it possible to limit a part in which the air bubble becomes a void as a result of resin curing or a part with a burr, to a part opposed to the non-mounting region on which the electronic components are not mounted. Accordingly, no electronic components are disposed at a part with a burr or a void. As a result, it is possible to suppress a decrease in waterproof property caused by a burr or a void.

### BRIEF DESCRIPTION OF THE FIGURES

FIG. 1 is a diagram illustrating a plan configuration example of a circuit board according to an embodiment of the present technology.

FIG. 2 is a diagram illustrating a plan configuration example of a wiring board illustrated in FIG. 1.

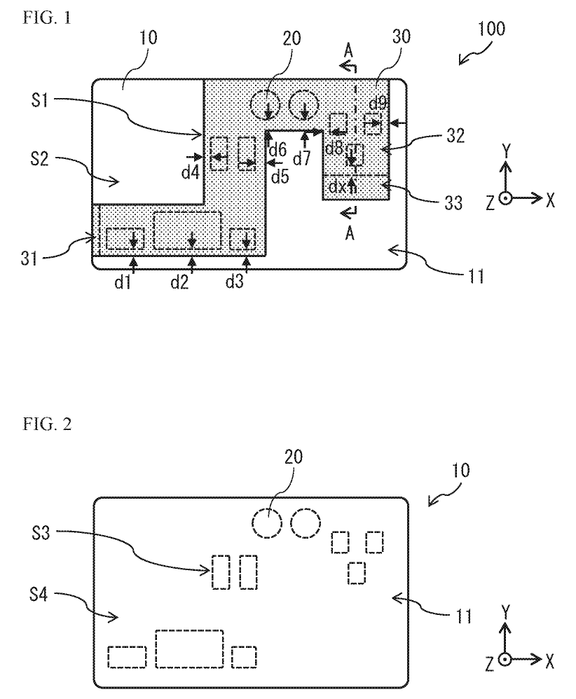

Part (A) of FIG. 3 is a diagram illustrating a sectional configuration example of the circuit board illustrated in FIG. 1, taken along line A-A. Part (B) of FIG. 3 is a diagram illustrating a plan configuration example of a resin part illustrated in Part (A) of FIG. 3.

Part (A) of FIG. 4 is a diagram illustrating a plan configuration example of a lower mold. Part (B) of FIG. 4 is a diagram illustrating a sectional configuration example of the lower mold illustrated in Part (A) of FIG. 4, taken along line A-A.

Part (A) of FIG. 5 is a diagram illustrating a plan configuration example of an upper mold. Part (B) of FIG. 5 is a diagram illustrating a sectional configuration example of the upper mold illustrated in Part (A) of FIG. 5, taken along line A-A. Part (C) of FIG. 5 is a diagram illustrating a sectional configuration example of the upper mold illustrated in Part (A) of FIG. 5, taken along line B-B.

FIG. 6 is a flowchart illustrating an example of a procedure of manufacturing the circuit board illustrated in FIG. 1.

Part (A) of FIG. 7 is a diagram illustrating a modification example of the sectional configuration of the circuit board illustrated in FIG. 1, taken along line A-A. Part (B) of FIG. 7 is a diagram illustrating a plan configuration example of the resin part illustrated in Part (A) of FIG. 7.

Part (A) of FIG. 8 is a diagram illustrating a modification example of the sectional configuration of the circuit board illustrated in FIG. 1, taken along line A-A. Part (B) of FIG. 8 is a diagram illustrating a plan configuration example of the resin part illustrated in Part (A) of FIG. 8.

Part (A) of FIG. 9 is a diagram illustrating a modification example of the sectional configuration of the circuit board illustrated in FIG. 1, taken along line A-A. Part (B) of FIG. 9 is a diagram illustrating a plan configuration example of the resin part illustrated in Part (A) of FIG. 9.

FIG. 10 is a diagram illustrating a modification example of the sectional configuration of the circuit board illustrated in FIG. 1, taken along the line A-A.

FIG. 11 is a diagram illustrating a sectional configuration example of the upper mold for forming the resin part illustrated in FIG. 10.

FIG. 12 is a diagram illustrating a modification example of a plan configuration example of a surface, of the circuit board illustrated in FIG. 1, on a first major surface side.

FIG. 13 is a diagram illustrating a plan configuration example of a surface, of the circuit board illustrated in FIG. 12, on a second major surface side.

FIG. 14 is a diagram illustrating a side surface configuration example of the circuit board illustrated in FIG. 12.

FIG. 15 is a diagram illustrating a sectional configuration example of the circuit board illustrated in FIGS. 12 and 13, taken along line A-A.

Part (A) of FIG. 16 is a diagram illustrating a modification example of the plan configuration of the lower mold. Part (B) of FIG. 16 is a diagram illustrating a sectional configuration example of the lower mold illustrated in Part (A) of FIG. 16, taken along line A-A.

Part (A) of FIG. 17 is a diagram illustrating a modification example of the plan configuration of the upper mold. Part (B) of FIG. 17 is a diagram illustrating a sectional configuration example of the upper mold illustrated in Part (A) of FIG. 17, taken along line A-A. Part (C) of FIG. 17 is a diagram illustrating a sectional configuration example of the upper mold illustrated in Part (A) of FIG. 17, taken along line B-B.

FIG. 18 is a diagram illustrating a modification example of the plan configuration of the surface, of the circuit board illustrated in FIG. 1, on the first major surface side.

FIG. 19 is a diagram illustrating a plan configuration example of the surface, of the circuit board illustrated in FIG. 18, on the second major surface side.

FIG. 20 is a diagram illustrating a side surface configuration example of the circuit board illustrated in FIG. 18.

FIG. 21 is a diagram illustrating a sectional configuration example of the circuit board illustrated in FIGS. 18 and 19, taken along line A-A.

Part (A) of FIG. 22 is a diagram illustrating a modification example of the plan configuration of the lower mold. Part (B) of FIG. 22 is a diagram illustrating a sectional configuration example of the lower mold illustrated in Part (A) of FIG. 22, taken along line A-A.

Part (A) of FIG. 23 is a diagram illustrating a modification example of the plan configuration of the upper mold. Part (B) of FIG. 23 is a diagram illustrating a sectional configuration example of the upper mold illustrated in Part (A) of FIG. 23, taken along line A-A. Part (C) of FIG. 23 is a diagram illustrating a sectional configuration example of the upper mold illustrated in Part (A) of FIG. 23, taken along line B-B.

FIG. 24 is a diagram illustrating a modification example of the plan configuration of the surface, of the circuit board illustrated in FIG. 1, on the first major surface side.

FIG. 25 is a diagram illustrating a plan configuration example of the surface, of the circuit board illustrated in FIG. 24, on the second major surface side.

FIG. 26 is a diagram illustrating a sectional configuration example of the circuit board illustrated in FIGS. 24 and 25, taken along line A-A.

FIG. 27 is a diagram illustrating a perspective configuration example of a battery pack.

[FIG. 28] FIG. 28 is a diagram illustrating a perspective configuration example of a battery module that is one of contents of the battery pack illustrated in FIG. 27.

FIG. 29 is a diagram illustrating an exploded perspective configuration example of the battery pack illustrated in FIG. 27.

### DETAILED DESCRIPTION

The present technology is described below in further detail including with reference to the drawings according to an embodiment.

First, a circuit board 100 according to an embodiment of the present technology will be described. FIG. 1 illustrates a plan configuration example of the circuit board 100. The circuit board 100 includes, for example, a wiring board 10 and a plurality of electronic components 20, as illustrated in FIG. 1. The wiring board 10 includes a first major surface 11. The electronic components 20 are mounted on the first major surface 11. The electronic components 20 mounted on the first major surface 11 include, for example, at least one component selected from a microcontroller, an integrated circuit (IC), a fuse, an energization busbar, a resistor, and a capacitor. For example, as the electronic components 20, at least one component selected from the microcontroller, the IC, the fuse, the energization busbar, the resistor, and the capacitor is mounted on the first major surface 11. The wiring board 10 corresponds to a specific example of a "wiring board" in an embodiment of the present technology. The electronic components 20 mounted on the first major surface 11 correspond to a specific example of a "plurality of electronic components" and a "plurality of first electronic components" in an embodiment of the present technology.

The circuit board 100 further includes, for example, a resin part 30 provided in contact with only a part of the first major surface 11, but not the entire first major surface 11, as illustrated in FIG. 1. The resin part 30 in contact with the first major surface 11 corresponds to a specific example of a "resin part" and a "first resin part" in an embodiment of the present technology. The resin part 30 covers the electronic components 20, and is a single, continuous part. The resin part 30 includes a waterproof resin material that makes it possible to protect the electronic components 20 from, for example, moisture in atmospheric air or submersion of the circuit board 100. The resin part 30 includes at least one resin material selected from the group consisting of polyamide, polyester, and polyurethane.

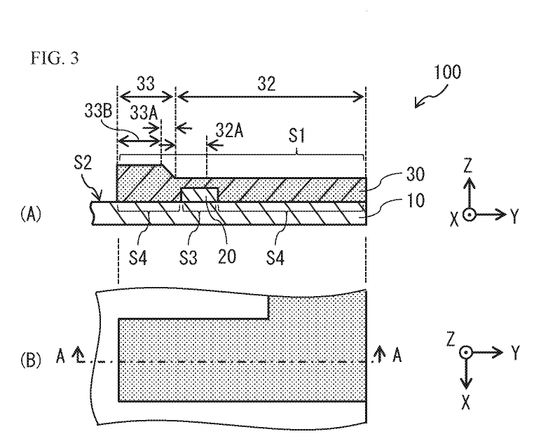

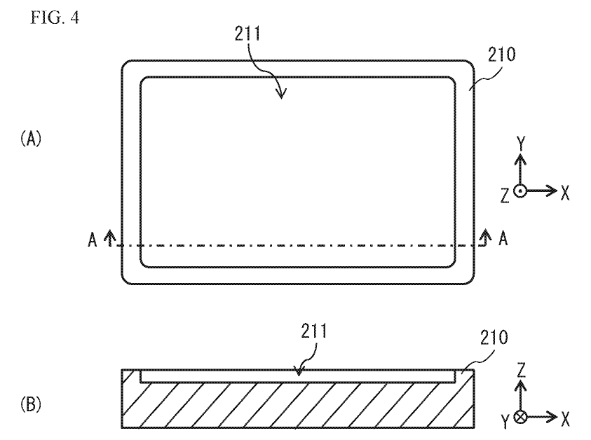

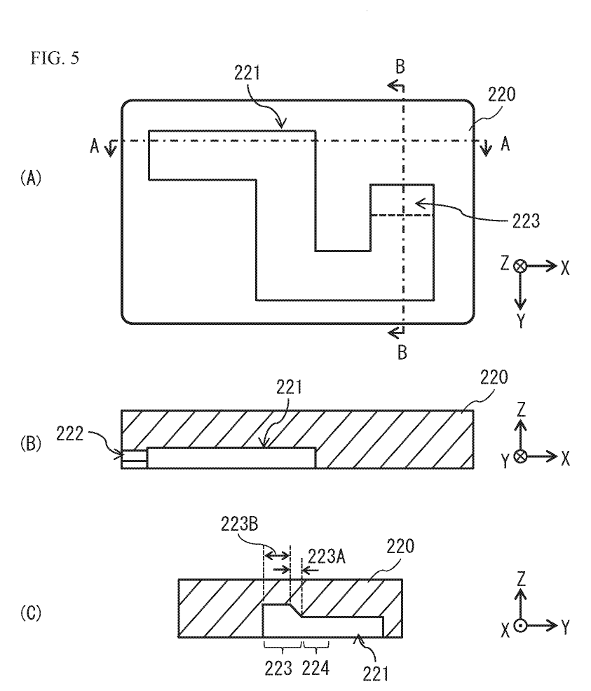

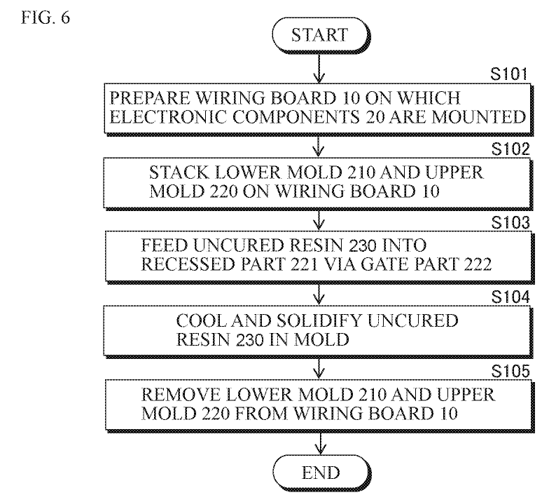

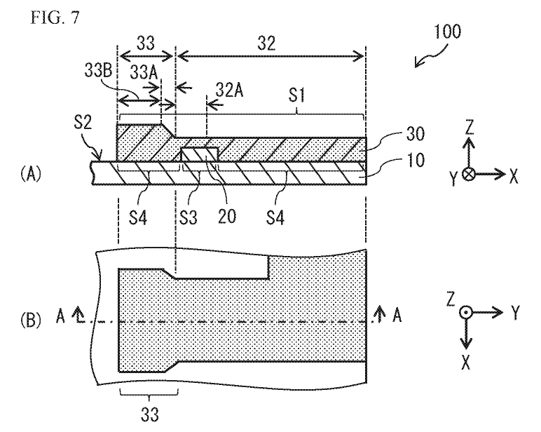

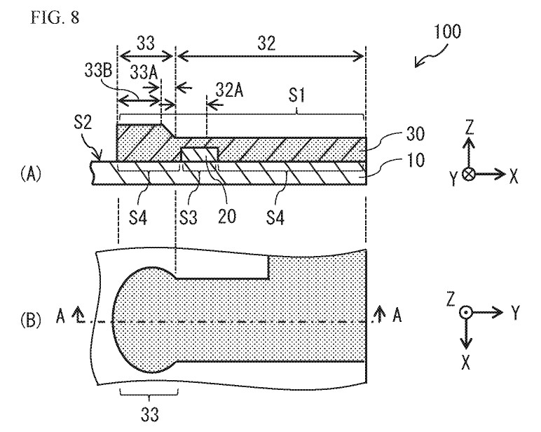

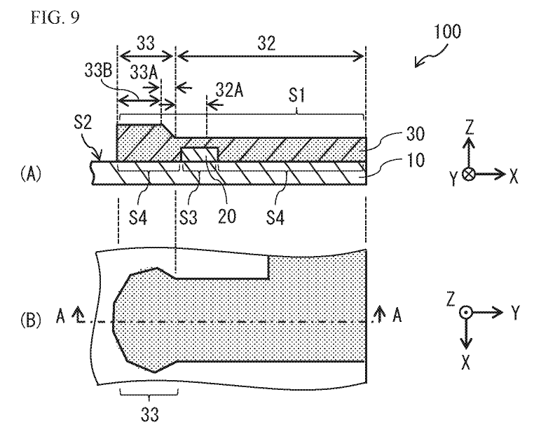

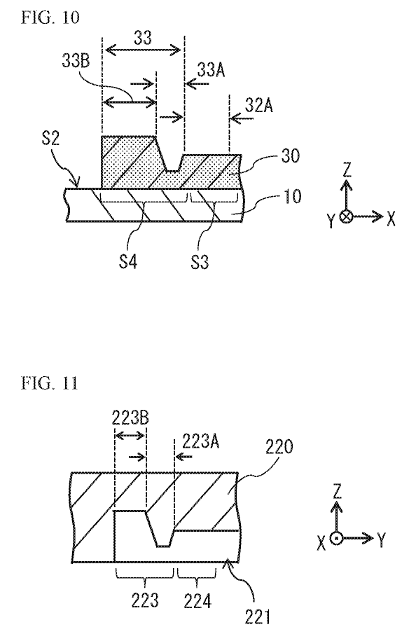

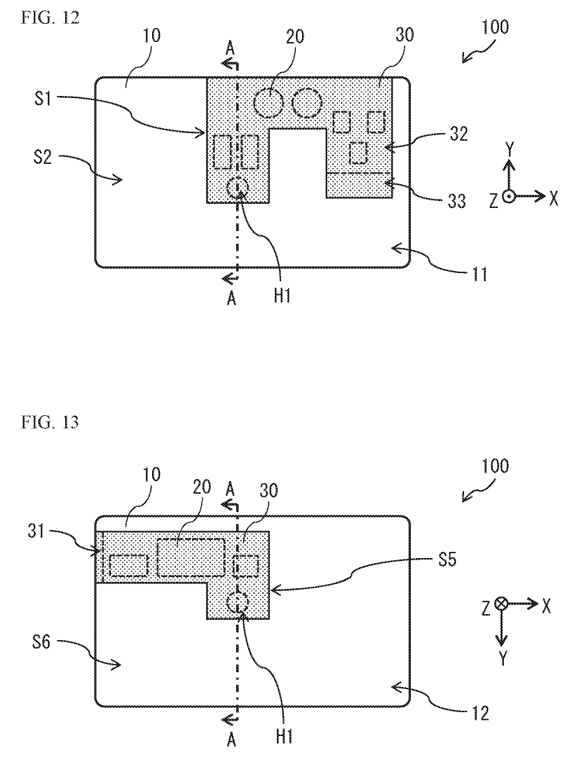

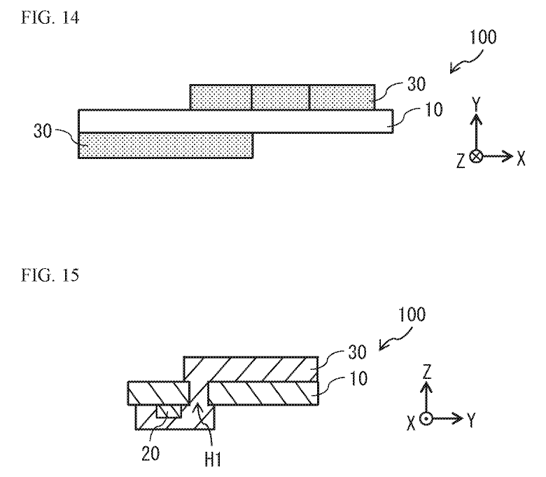

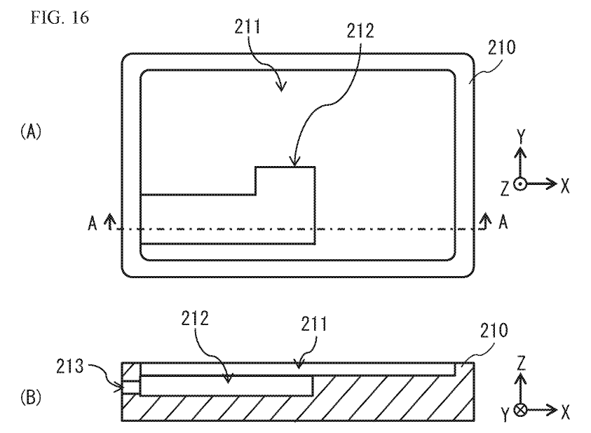

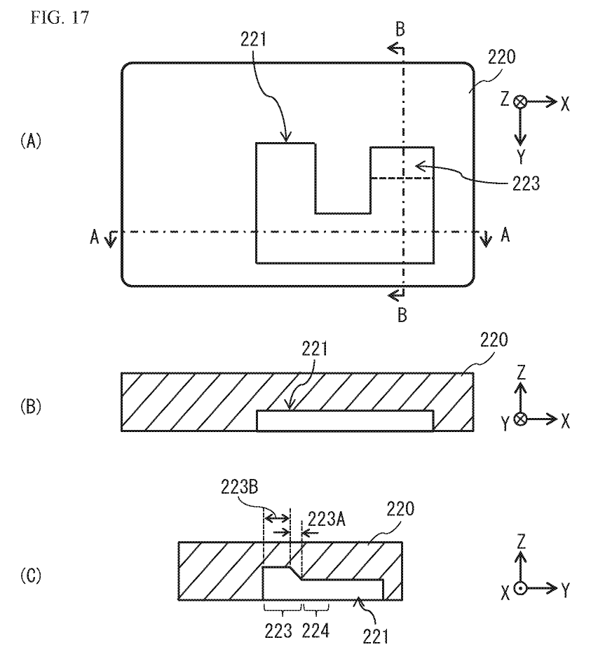

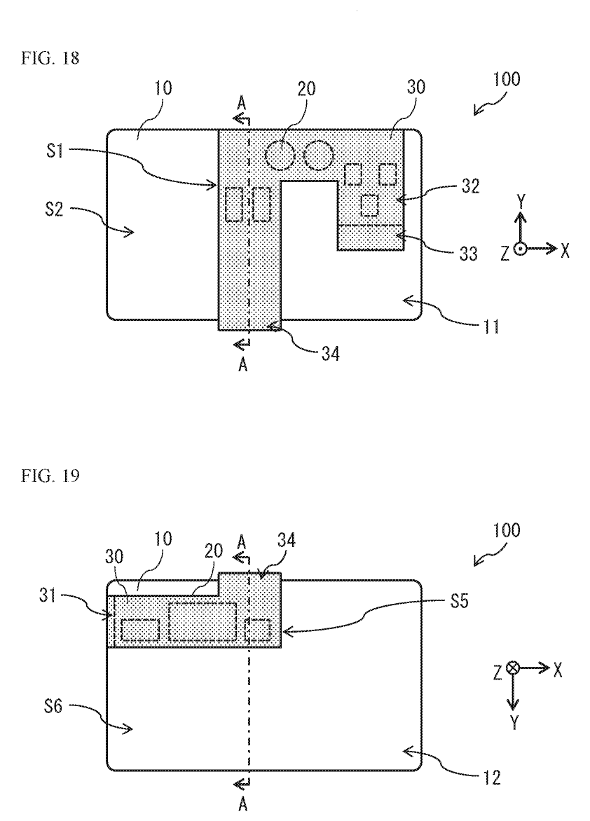

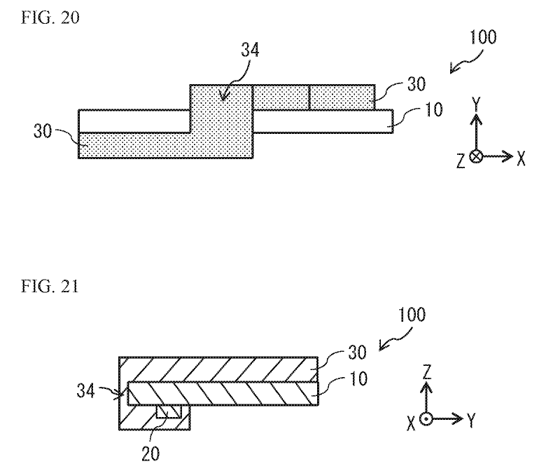

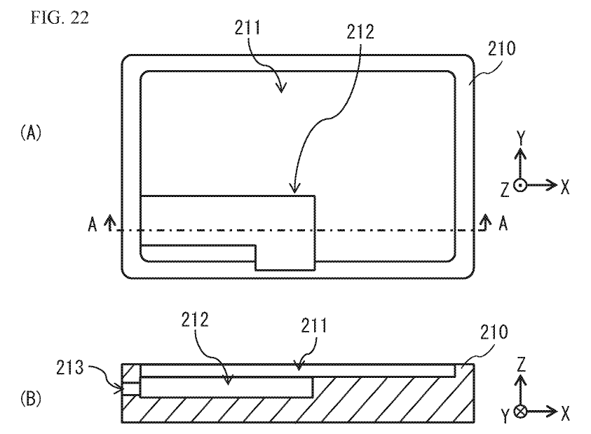

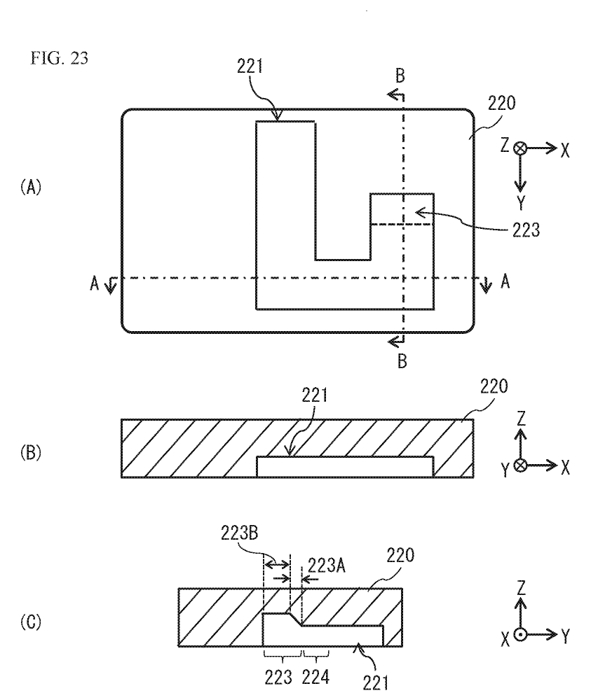

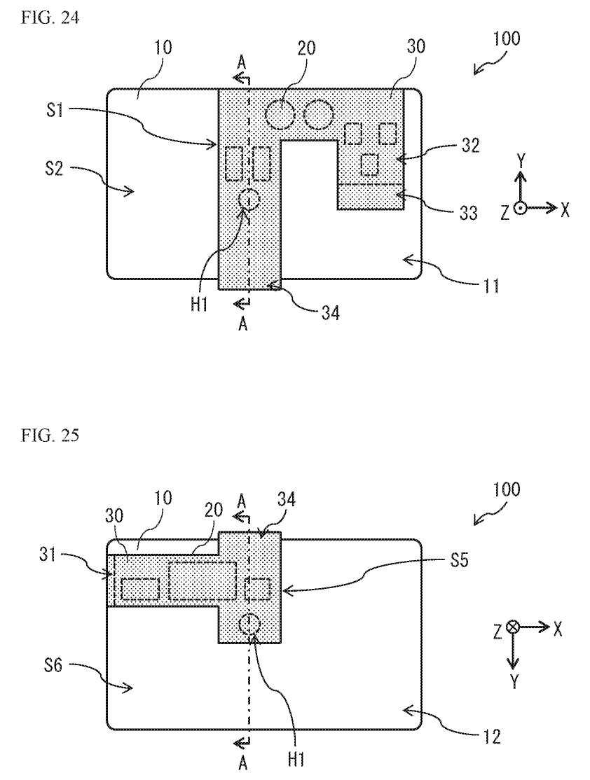

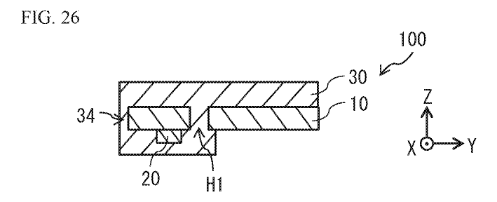

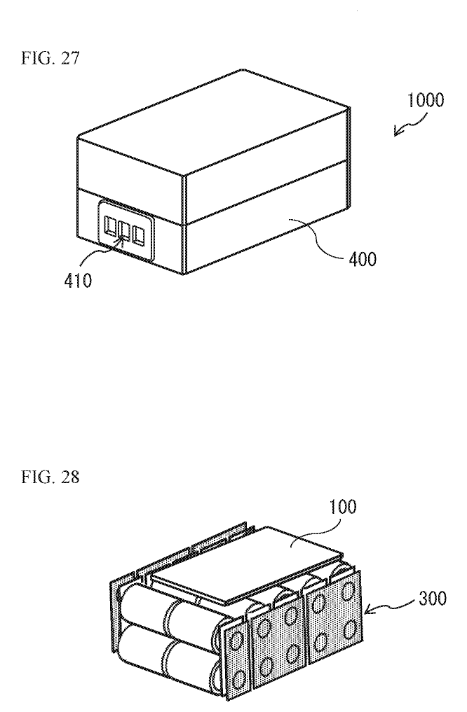

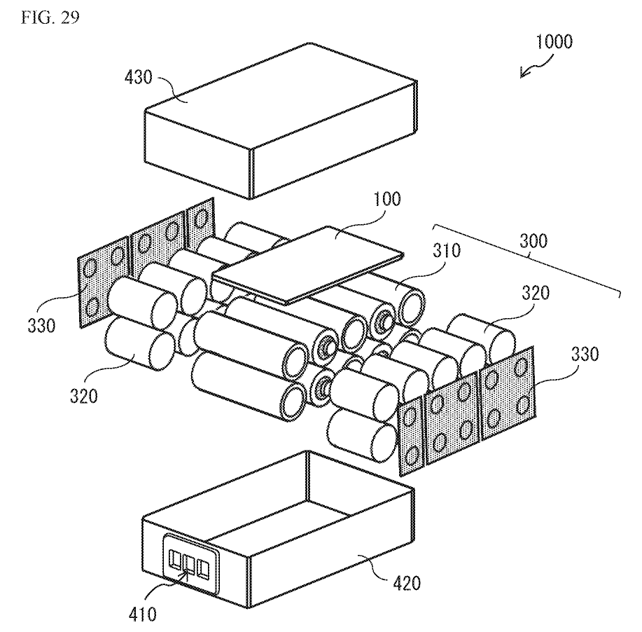

The wiring board 10 is a plate-shaped component including an insulating substrate on which an electrically conductive metal is provided as wiring. The wiring board 10 is a printed wiring board (PWB) to which the electronic components 20 are not yet attached. The wiring board 10 may be a plate-shaped component in which wiring is provided on a surface of a single insulating substrate. The wiring board 10 may be a plate-shaped component in which wiring is provided on a surface of and inside a stacked body. The stacked body includes a plurality of insulating substrates stacked on each other. The first major surface 11 of the wiring board 10 includes, for example, a covered region S1 that is a single, continuous region covered with the resin part 30, and an uncovered region S2 that is not covered with the resin part 30, as illustrated in FIG. 1. As illustrated in FIG. 2, the first major surface 11 of the wiring board 10 includes, for example, a mounting region S3 on which the electronic components 20 are mounted, and a non-mounting region S4 on which the electronic components 20 are not mounted. FIG. 2 illustrates a plan configuration example of the first major surface 11 of the wiring board 10. The covered region S1 corresponds to a specific example of a "covered region" in an embodiment of the present technology. The uncovered region S2 corresponds to a specific example of an "uncovered region" in an embodiment of the present technology. The non-mounting region S4 corresponds to a specific example of a "non-mounting region" in an embodiment of the present technology.

The mounting region S3 is provided with a plurality of pad electrodes adapted to electrically couple the electronic components 20 and the wiring of the wiring board 10 to each other. The non-mounting region S4 is not provided with the above-described pad electrodes, and a surface of the insulating substrate or a thin film covering the surface of the insulating substrate is exposed. For example, as illustrated in FIG. 1, the resin part 30 extends from a gate part 31 in contact with an edge of the wiring board 10 to an end part 33 in contact with the non-mounting region S4.

The end part 33 is positioned to be spaced away from the edge of the wiring board 10, and has a shape with three sides surrounded by the uncovered region S2. The end part 33 has, for example, a rectangular shape in a plan view. The end part 33 occupies, for example, an area smaller than an area occupied by the electronic component 20 having the largest size among the electronic components 20 mounted on the wiring board 10. The end part 33 occupies, for example, an area in which an air bubble having the largest size among air bubbles that can be generated in a later-described manufacturing process is containable. The area occupied by the end part 33 is 1 mm or greater × 1 mm or greater. The air bubble having the largest size is, for example, an air bubble having a diameter of about 1 mm. The end part 33 is positioned farthest from the gate part 31, along an outline of the resin part 30. A part, i.e., a middle part 32, of the resin part 30, between the gate part 31 and the end part 33, may have, for example, a band shape that extends from the gate part 31 to the end part 33, as illustrated in FIG. 1. The part, i.e., the middle part 32, of the resin part 30, between the gate part 31 and the end part 33, may have, for example, a non-band shape that has different widths in different portions. The middle part 32 is, for example, partly in contact with the edge of the wiring board 10, as illustrated in FIG. 1. The middle part 32 may be disposed only at a position spaced away from the edge of the wiring board 10.

The end part 33 refers to a part that is spaced away, by a predetermined distance dx, from the electronic component 20 closest to the end part 33 among the electronic components 20 covered with the middle part 32. The predetermined distance dx corresponds to a thickness of the resin part 30 that is necessary to waterproof the electronic components 20. The predetermined distance dx is equal to the longest distance (e.g., d7 in FIG. 1) among distances (e.g., d1 to d9 in FIG. 1) between a side surface of the resin part 30 and respective side surfaces of the electronic components 20 in a plan view of the resin part 30.

Part (A) of FIG. 3 illustrates a sectional configuration example of the circuit board 100 illustrated in FIG. 1, taken along line A-A. Part (B) of FIG. 3 illustrates a plan configuration example of the resin part 30 illustrated in Part (A) of FIG. 3. The sectional configuration illustrated in Part (A) of FIG. 3 corresponds to a sectional configuration taken along the line A-A illustrated in Part (B) of FIG. 3. For example, as illustrated in Part (A) of FIG. 3, the end part 33 has a part, i.e., a second part 33B, having a thickness that is greater than a thickness of an adjacent part 32A. The adjacent part 32A is a part, of the resin part 30 or the middle part 32, that is adjacent to the end part 33. The end part 33 also has, for example, a shape in which a thickness of the end part 33 increases with an increase in distance from the adjacent part 32A, as illustrated in Part (A) of FIG. 3. The end part 33 has the shape in which the thickness of the end part 33 increases with an increase in distance from the adjacent part 32A, at a part, i.e., a first part 33A, between the adjacent part 32A and the second part 33B. The resin part 30 is a molded resin formed by low-pressure molding using a mold. The resin part 30 has a three-dimensional shape corresponding to a shape of a recessed part 221 of an upper mold 220 to be described later. Herein, the "low-pressure molding" refers to molding under conditions of 90℃ to 240℃ and 3 kgf/cm² to 50 kgf/cm².

A description is given next of a method of manufacturing the circuit board 100. First, molds, i.e., a lower mold 210 and the upper mold 220, to be used in the process of manufacturing the circuit board 100 will be described. Thereafter, a method of manufacturing the circuit board 100 using the molds, i.e., the lower mold 210 and the upper mold 220, will be described.

Part (A) of FIG. 4 illustrates a plan configuration example of the lower mold 210. Part (B) of FIG. 4 illustrates a sectional configuration example of the lower mold 210 illustrated in Part (A) of FIG. 4, taken along line A-A. Part (A) of FIG. 5 illustrates a plan configuration example of the upper mold 220. Part (B) of FIG. 5 illustrates a sectional configuration example of the upper mold 220 illustrated in Part (A) of FIG. 5, taken along line A-A. Part (C) of FIG. 5 illustrates a sectional configuration example of the upper mold 220 illustrated in Part (A) of FIG. 5, taken along line B-B.

For example, as illustrated in Parts (A) and (B) of FIG. 4, the lower mold 210 includes a receiving part 211 that receives the wiring board 10. For example, as illustrated in Parts (A), (B), and (C) of FIG. 5, the upper mold 220 includes the recessed part 221. The recessed part 221 is a single, continuous part positioned to be opposed to a covering target region, when the upper mold 220 is stacked on the wiring board 10. The covering target region is a single, continuous region that is a part of the first major surface 11 and includes the electronic components 20.

The recessed part 221 has a three-dimensional shape corresponding to the shape of the resin part 30. The recessed part 221 has one end to which a gate part 222 is coupled. The gate part 222 is a gap that allows the one end of the recessed part 221 to communicate with an outside. The gate part 222 serves as an inlet through which an uncured resin 300, which will be described later, is fed into the upper mold 220. The recessed part 221 has another end that is an end part 223. The end part 223 is positioned to be opposed to the non-mounting region S4, of the first major surface 11, on which the electronic components 20 are not mounted, when the upper mold 220 is stacked on the wiring board 10. The end part 223 is positioned farthest from the gate part 222, along an outline of the recessed part 221. For example, as illustrated in Part (A) of FIG. 5, a part, of the recessed part 221, between the gate part 222 and the end part 223 may have a band shape that extends from the gate part 222 to the end part 223, or may have a non-band shape that has different widths in different portions.

For example, as illustrated in Part (C) of FIG. 5, the end part 223 has a part, i.e., a second part 223B, having a thickness that is greater than a thickness of an adjacent part 224. The adjacent part 224 is a part, of the recessed part 221, that is adjacent to the end part 223. The end part 223 further has, for example, a shape in which a thickness of the end part 223 increases with an increase in distance from the adjacent part 224, as illustrated in Part (C) of FIG. 5. The end part 223 has the shape in which the thickness of the end part 223 increases with an increase in distance from the adjacent part 224, at a part, i.e., a first part 223A, between the adjacent part 224 and the second part 223B.

FIG. 6 illustrates an example of a procedure of manufacturing the circuit board 100. First, the wiring board 10 on which the electronic components 20 are mounted is prepared (step S101). Thereafter, the lower mold 210 and the upper mold 220 are stacked on the wiring board 10 (step S102). Thereafter, the uncured resin 300 is injected into the gate part 222 of the upper mold 220 to thereby feed the uncured resin 300 into the recessed part 221 through the gate part 222 (step S103). The uncured resin 300 is a raw material of the resin part 30, and includes, for example, at least one thermoplastic resin selected from the group consisting of polyamide, polyester, and polyurethane.

In a process in which the uncured resin 300 is fed into the recessed part 221, air bubbles can be generated in the uncured resin 300 due to a three-dimensional structure of the electronic components 20 disposed in the recessed part 221. When air bubbles are generated in the uncured resin 300, the air bubbles in the uncured resin 300 move toward the end part 223 and are eventually accumulated at the end part 223, i.e., a flow end. In the end part 223, a pressure on the uncured resin 300 can sometimes increase locally. In such a case, the uncured resin 300 can leak out of the end part 223. Note that in the process in which the uncured resin 300 is fed into the recessed part 221, a gas remaining in the recessed part 221 or a gas generated in the recessed part 221 is, for example, discharged to the outside through a vent of the upper mold 220.

Thereafter, the uncured resin 300 is cooled and solidified in the molds, i.e., the lower mold 210 and the upper mold 220 (step S104). As a result, the resin part 30 is formed. Here, the air bubbles accumulated in the end part 223 become voids in the end part 33. In addition, the uncured resin 300 leaked out of the end part 223 becomes a burr of the end part 33. Lastly, the molds, i.e., the lower mold 210 and the upper mold 220, are removed from the wiring board 10. The wiring board 100 is thus manufactured.

In the manufactured wiring board 100, a part, of the resin part 30, other than the end part 33 is less prone to have voids or burrs, while the end part 33 can have voids or burrs. Because the end part 33 is not provided with the electronic components 20, there is a very low possibility that, for example, moisture in the atmospheric air reaches the electronic components 20 via a void or a burr in the end part 33.

Next, effects of the circuit board 100 will be described.

In the present embodiment, the resin part 33 has the end part 33 in contact with the non-mounting region S4. This makes it possible to concentrate, in the end part 33, voids and burrs to be generated in the resin part 33 in the manufacturing process. Because the electronic components 20 are not present in the end part 33, there is a very low possibility that, for example, moisture in the atmospheric air reaches the electronic components 20 via a void or a burr in the end part 33. Therefore, it is possible to suppress a decrease in waterproof property caused by a burr or a void.

In the present embodiment, the end part 33 is positioned to be spaced away from the edge of the wiring board 10, and has three sides surrounded by the uncovered region S2. This makes it possible to concentrate, in the end part 33, voids and burrs to be generated in the resin part 33 in the manufacturing process. Because the electronic components 20 are not present in the end part 33, there is a very low possibility that, for example, moisture in the atmospheric air reaches the electronic components 20 via a void or a burr in the end part 33. Therefore, it is possible to suppress a decrease in the waterproof property caused by a burr or a void.

In the present embodiment, the end part 33 is positioned farthest from the gate part 31, along the outline of the resin part 30. This makes it possible to concentrate, in the end part 33, voids and burrs to be generated in the resin part 33 in the manufacturing process. Because the electronic components 20 are not present in the end part 33, there is a very low possibility that, for example, moisture in the atmospheric air reaches the electronic components 20 via a void or a burr in the end part 33. Therefore, it is possible to suppress a decrease in the waterproof property caused by a burr or a void.

In the present embodiment, the end part 33 has the part, i.e., the second part 33B, having the thickness that is greater than the thickness of the adjacent part 32A. This makes it possible to smoothly feed the uncured resin 300 into the part, i.e., the second part 223B, corresponding to the second part 33B, and to thus concentrate, in the end part 33, voids and burrs to be generated in the resin part 33 in the manufacturing process. Because the electronic components 20 are not present in the end part 33, there is a very low possibility that, for example, moisture in the atmospheric air reaches the electronic components 20 via a void or a burr in the end part 33. Therefore, it is possible to suppress a decrease in the waterproof property caused by a burr or a void.

In the present embodiment, the end part 33 further has the shape in which the thickness of the end part 33 increases with an increase in distance from the adjacent part 32A. This makes it possible to smoothly feed the uncured resin 300 into the part, i.e., the second part 223B, corresponding to the second part 33B, and to thus concentrate, in the end part 33, voids and burrs to be generated in the resin part 33 in the manufacturing process. Because the electronic components 20 are not present in the end part 33, there is a very low possibility that, for example, moisture in the atmospheric air reaches the electronic components 20 via a void or a burr in the end part 33. Therefore, it is possible to suppress a decrease in the waterproof property caused by a burr or a void.

Next, effects of the method of manufacturing the circuit board 100 will be described.

In the present embodiment, the uncured resin 300 is fed into the recessed part 221 of the upper mold 220 stacked on the wiring board 10. The recessed part 221 includes the end part 223 positioned to be opposed to the non-mounting region S4, of the first major surface 11, on which the electronic components 20 are not mounted, when the upper mold 220 is stacked on the wiring board 10. This makes it possible to concentrate, in the end part 223, air bubbles to be generated or leakage of the uncured resin 300 in the manufacturing process. As a result, it is possible to concentrate, in the end part 33, voids and burrs to be generated in the resin part 33. Because the electronic components 20 are not present in the end part 33, there is a very low possibility that, for example, moisture in the atmospheric air reaches the electronic components 20 via a void or a burr in the end part 33. Therefore, it is possible to suppress a decrease in the waterproof property caused by a burr or a void.

In the present embodiment, the end part 223 is positioned farthest from the gate part 222, along the outline of the recessed part 221. This makes it possible to concentrate, in the end part 223, air bubbles to be generated or leakage of the uncured resin 300 in the manufacturing process. As a result, it is possible to concentrate, in the end part 33, voids and burrs to be generated in the resin part 33. Because the electronic components 20 are not present in the end part 33, there is a very low possibility that, for example, moisture in the atmospheric air reaches the electronic components 20 via a void or a burr in the end part 33. Therefore, it is possible to suppress a decrease in the waterproof property caused by a burr or a void.

In the present embodiment, the end part 223 has the part, i.e., the second part 223B, having the thickness that is greater than the thickness of the adjacent part 224. This makes it possible to smoothly feed the uncured resin 300 into the second part 223B in the manufacturing process, and to thus concentrate, in the end part 223, air bubbles to be generated or leakage of the uncured resin 300 in the manufacturing process. As a result, it is possible to concentrate, in the end part 33, voids and burrs to be generated in the resin part 33. Because the electronic components 20 are not present in the end part 33, there is a very low possibility that, for example, moisture in the atmospheric air reaches the electronic components 20 via a void or a burr in the end part 33. Therefore, it is possible to suppress a decrease in the waterproof property caused by a burr or a void.

In the present embodiment, the end part 223 further has the shape in which the thickness of the end part 223 increases with an increase in distance from the adjacent part 224. This makes it possible to smoothly feed the uncured resin 300 into the second part 223B in the manufacturing process, and to thus concentrate, in the end part 223, air bubbles to be generated or leakage of the uncured resin 300 in the manufacturing process. As a result, it is possible to concentrate, in the end part 33, voids and burrs to be generated in the resin part 33. Because the electronic components 20 are not present in the end part 33, there is a very low possibility that, for example, moisture in the atmospheric air reaches the electronic components 20 via a void or a burr in the end part 33. Therefore, it is possible to suppress a decrease in the waterproof property caused by a burr or a void.

Next, modification examples of the circuit board 100 will be described according to an embodiment.

In the above-described embodiment, as illustrated in Parts (A) and (B) of FIG. 7, the end part 33 or the first part 33A may have, for example, a tapered shape having a width that increases with an increase in distance from the adjacent part 32A. In this case, the end part 223 also has a tapered shape having a width that increases with an increase in distance from the adjacent part 224. This makes it possible to smoothly feed the uncured resin 300 into the second part 223B in the manufacturing process, and to thus concentrate, in the end part 223, air bubbles to be generated or leakage of the uncured resin 300 in the manufacturing process. As a result, it is possible to concentrate, in the end part 33, voids and burrs to be generated in the resin part 33. Because the electronic components 20 are not present in the end part 33, there is a very low possibility that, for example, moisture in the atmospheric air reaches the electronic components 20 via a void or a burr in the end part 33. Therefore, it is possible to suppress a decrease in the waterproof property caused by a burr or a void.

In the embodiment and Modification example A described above, as illustrated in Parts (A) and (B) of FIG. 8, the end part 33 may have, for example, a circular shape or an elliptical shape in a plan view. In this case, the end part 223 also has a circular shape or an elliptical shape in a plan view. This makes it possible to reduce local concentration of pressure in the end part 223, and to thus suppress leakage of the uncured resin 300 from the end part 223. Therefore, it is possible to suppress a decrease in the waterproof property caused by a burr.

In the embodiment and Modification example A described above, as illustrated in Parts (A) and (B) of FIG. 9, the end part 33 may have, for example, a polygonal shape similar to a circular shape or an elliptical shape in a plan view. In this case, the end part 223 also has a polygonal shape similar to a circular shape or an elliptical shape in a plan view. This makes it possible to reduce local concentration of pressure in the end part 223, and to thus suppress leakage of the uncured resin 300 from the end part 223. Therefore, it is possible to suppress a decrease in the waterproof property caused by a burry.

In the embodiment and Modification examples A, B, and C described above, as illustrated in FIG. 10, the end part 33 may have, for example, the part, i.e., the first part 33A, close to the adjacent part 32A, in which the thickness of the end part 33 is smaller than the thickness of the adjacent part 32A. In this case, the end part 223 has, for example, the part, i.e., the first part 223A, close to the adjacent part 224, in which the thickness of the end part 223 is smaller than the thickness of the adjacent part 224, as illustrated in FIG. 11. This makes it possible to temporarily accumulate air bubbles in a part before the first part 223A, and thereafter, when a filling pressure rises, to cause the accumulated air bubbles to flow at once into the second part 223B in the manufacturing process. As a result, it is possible to concentrate, in the end part 33, voids and burrs to be generated in the resin part 33. Because the electronic components 20 are not present in the end part 33, there is a very low possibility that, for example, moisture in the atmospheric air reaches the electronic components 20 via a void or a burr in the end part 33. Therefore, it is possible to suppress a decrease in the waterproof property caused by a burr or a void.

In the embodiment and Modification examples A, B, C, and D described above, as illustrated in FIGS. 12, 13, and 15, the wiring board 10 may have, for example, a through hole H1. The through hole H1 corresponds to a specific example of a "through hole" in an embodiment of the present technology. FIG. 12 illustrates a modification example of the plan configuration of the surface, of the circuit board 100, on the first major surface 11 side. FIG. 13 illustrates a plan configuration example of a surface, of the circuit board 100, on a second major surface 12 side. FIG. 15 illustrates a sectional configuration example of the circuit board 100 illustrated in FIGS. 12 and 13, taken along line A-A. The second major surface 12 corresponds to a surface opposed to the first major surface 11 of the wiring board 10.

In the present modification example, the electronic components 20 are mounted also on the second major surface 12 of the wiring board 10, and the electronic components 20 mounted on the second major surface 12 are covered with a part of the gate part 22 and a part of the middle part 23 of the resin part 30. The electronic components 20 mounted on the second major surface 12 include, for example, at least one component selected from a microcontroller, an IC, a fuse, an energization busbar, a resistor, and a capacitor. For example, as the electronic components 20, at least one component selected from the microcontroller, the IC, the fuse, the energization busbar, the resistor, and the capacitor is mounted on the second major surface 12. The electronic components 20 mounted on the second major surface 12 correspond to a specific example of "second electronic components" in an embodiment of the present technology. As illustrated in FIG. 14, the resin part 30 includes, for example, a part in contact with the first major surface 11 and a part in contact with the second major surface 12. The part, of the resin part 30, in contact with the second major surface 12 corresponds to a specific example of a "second resin part" in an embodiment of the present technology. FIG. 14 illustrates a side surface configuration example of the circuit board 100 illustrated in FIG. 12. As illustrated in FIG. 15, the resin part 30 further includes, for example, a part that fills the through hole H1 and is coupled to the part, of the resin part 30, in contact with the first major surface 11 and the part, of the resin part 30, in contact with the second major surface 12. As illustrated in FIG. 13, the resin part 30 includes, for example, a covered region S5 and an uncovered region S6 on the second major surface 12. The covered region S5 is a single, continuous region covered with the resin part 30. The uncovered region S6 is not covered with the resin part 30. The through hole H1 is provided in the covered regions S1 and S5. In the present modification example, the end part 33 of the resin part 30 has the configuration described in any of the embodiment and Modification examples A, B, C, and D described above.

Part (A) of FIG. 16 illustrates a modification example of the plan configuration of the lower mold 210. Part (B) of FIG. 16 illustrates a sectional configuration example of the lower mold 210 illustrated in Part (A) of FIG. 16, taken along line A-A. Part (A) of FIG. 17 illustrates a modification example of the plan configuration of the upper mold 220. Part (B) of FIG. 17 illustrates a sectional configuration example of the upper mold 220 illustrated in Part (A) of FIG. 17, taken along line A-A. Part (C) of FIG. 17 illustrates a sectional configuration example of the upper mold 220 illustrated in Part (A) of FIG. 17, taken along line B-B.

In the present modification example, as illustrated in Parts (A) and (B) of FIG. 16, the lower mold 210 includes, for example, the receiving part 211 and a recessed part 212. The receiving part 211 receives the wiring board 10. The recessed part 212 is, for example, a single, continuous part positioned to be opposed to a covering target region, when the lower mold 210 is stacked on the wiring board 10, as illustrated in Parts (A) and (B) of FIG. 16. The covering target region is a single, continuous region that is a part of the second major surface 12 and includes the electronic components 20.

The recessed part 212 has a three-dimensional shape corresponding to a shape of a part of the resin part 30 on the second major surface 12 side. The recessed part 212 has one end to which a gate part 213 is coupled. The gate part 213 is a gap that allows the one end of the recessed part 212 to communicate with the outside. The gate part 213 serves as an inlet through which the uncured resin 300 is fed into the lower mold 210. The recessed part 212 has another end that is positioned to be opposed to the through hole H1 of the wiring board 10, when the lower mold 210 is stacked on the wiring board 10.

In the present modification example, the upper mold 220 has, for example, the recessed part 221, as illustrated in Parts (A), (B), and (C) of FIG. 17. The recessed part 221 is a single, continuous part that is positioned to be opposed to the covering target region, when the upper mold 220 is stacked on the wiring board 10. The covering target region is a single, continuous region that is a part of the first major surface 11 and includes the electronic components 20.

The recessed part 221 has a three-dimensional shape corresponding to a shape of a part of the resin part 30 on the first major surface 11 side. The recessed part 221 has one end that is positioned at a part to be opposed to the through hole H1 of the wiring board 10, when the upper mold 220 is stacked on the wiring board 10. The above-described part to be opposed to the through hole H1 of the wiring board 10 is hereinafter referred to as an "opposed part". The recessed part 221 has another end that is the end part 223. The end part 223 is positioned to be opposed to the non-mounting region S4, of the first major surface 11, on which the electronic components 20 are not mounted, when the upper mold 220 is stacked on the wiring board 10. The end part 223 is positioned farthest from the above-described opposed part, along the outline of the recessed part 221. For example, as illustrated in Part (A) of FIG. 17, a part, of the recessed part 221, between the above-described opposed part and the end part 223 may have a band shape that extends from the above-described opposed part to the end part 223, or may have a non-band shape that has different widths in different portions.

As illustrated in Part (C) of FIG. 17, the end part 223 has, for example, the part, i.e., the second part 223B, having the thickness that is greater than the thickness of the adjacent part 224. The adjacent part 224 is a part, of the recessed part 221, that is adjacent to the end part 223. The end part 223 further has, for example, the shape in which the thickness of the end part 223 increases with an increase in distance from the adjacent part 224, as illustrated in Part (C) of FIG. 17. The end part 223 has the shape in which the thickness of the end part 223 increases with an increase in distance from the adjacent part 224, at the part, i.e., the first part 223A, between the adjacent part 224 and the second part 223B.

In the present modification example, the uncured resin 300 is injected into the gate part 213 of the lower mold 210, thereby feeding the uncured resin 300 into the recessed part 212 via the gate part 213 in the manufacturing process. In this case, the uncured resin 300 in the recessed part 212 is fed into the recessed part 221 of the upper mold 220 via the through hole H1 of the wiring board 10.

In the process in which the uncured resin 300 is fed into the recessed parts 212 and 221, air bubbles can be generated in the uncured resin 300 due to the three-dimensional structure of the electronic components 20 disposed in the recessed parts 212 and 221. When air bubbles are generated in the uncured resin 300, the air bubbles in the uncured resin 300 move toward the end part 223 and are eventually accumulated at the end part 223, i.e., a flow end. In the end part 223, a pressure on the uncured resin 300 can sometimes increase locally. In such a case, the uncured resin 300 can leak out of the end part 223. Note that in the process in which the uncured resin 300 is fed into the recessed parts 212 and 221, a gas remaining in the recessed parts 212 and 221 or a gas generated in the recessed parts 212 and 221 is, for example, discharged to the outside through the vent of the upper mold 220.

In the present modification example, the resin part 33 includes a part in contact with the first major surface 11, a part in contact with the second major surface 12, and a part filling the through hole H1. In such a case, air bubbles are generated more easily in the uncured resin 300, as compared with the case of the above-described embodiment. However, the part, of the resin part 33, in contact with the first major surface 11 has the end part 33 in contact with the non-mounting region S4. This makes it possible to concentrate, in the end part 33, voids and burrs to be generated in the resin part 33 in the manufacturing process. Because the electronic components 20 are not present in the end part 33, there is a very low possibility that, for example, moisture in the atmospheric air reaches the electronic components 20 via a void or a burr in the end part 33. Therefore, it is possible to suppress a decrease in the waterproof property caused by a burr or a void.

In the embodiment and Modification examples A, B, C, and D described above, as illustrated in FIGS. 18, 19, 20, and 21, the resin part 30 may have a coupling part 34 positioned to be in contact with a side surface of the wiring board 10. The coupling part 34 is coupled to the part, of the resin part 30, in contact with the first major surface 11 and the part, of the resin part 30, in contact with the second major surface 12. The coupling part 34 corresponds to a specific example of a "third resin part" in an embodiment of the present technology. FIG. 18 illustrates a modification example of the plan configuration of the surface, of the circuit board 100, on the first major surface 11 side. FIG. 19 illustrates a plan configuration example of the surface, of the circuit board 100, on the second major surface 12 side. FIG. 20 illustrates a side surface configuration example of the circuit board 100 illustrated in FIG. 18. FIG. 21 illustrates a sectional configuration example of the circuit board 100 illustrated in FIGS. 18 and 19, taken along line A-A.

In the present modification example, the electronic components 20 are mounted also on the second major surface 12 of the wiring board 10, and the electronic components 20 mounted on the second major surface 12 are covered with a part of the gate part 22 and a part of the middle part 23 of the resin part 30. As illustrated in FIG. 19, the resin part 30 includes, for example, the covered region S5 and the uncovered region S6 on the second major surface 12. The covered region S5 is a single, continuous region covered with the resin part 30. The uncovered region S6 is not covered with the resin part 30. In the present modification example, the end part 33 of the resin part 30 has the configuration described in any of the embodiment and Modification examples A, B, C, and D described above.

Part (A) of FIG. 22 illustrates a modification example of the plan configuration of the lower mold 210. Part (B) of FIG. 22 illustrates a sectional configuration example of the lower mold 210 illustrated in Part (A) of FIG. 22, taken along line A-A. Part (A) of FIG. 23 illustrates a modification example of the plan configuration of the upper mold 220. Part (B) of FIG. 23 illustrates a sectional configuration example of the upper mold 220 illustrated in Part (A) of FIG. 23, taken along line A-A. Part (C) of FIG. 23 illustrates a sectional configuration example of the upper mold 220 illustrated in Part (A) of FIG. 23, taken along line B-B.

In the present modification example, as illustrated in Parts (A) and (B) of FIG. 22, the lower mold 210 includes, for example, the receiving part 211 and the recessed part 212. The receiving part 211 receives the wiring board 10. The recessed part 212 is, for example, a single, continuous part that is positioned to be opposed to the covering target region, when the lower mold 210 is stacked on the wiring board 10, as illustrated in Parts (A) and (B) of FIG. 22. The covering target region is a single, continuous region that is a part of the second major surface 12 and includes the electronic components 20.

The recessed part 212 has a three-dimensional shape corresponding to the shape of the part of the resin part 30 on the second major surface 12 side and a shape of a part of the resin part 30 on a side of a side surface of the wiring board 10. The recessed part 212 has one end to which the gate part 213 is coupled. The gate part 213 is a gap that allows the one end of the recessed part 212 to communicate with the outside. The gate part 213 serves as an inlet through which the uncured resin 300 is fed into the lower mold 210. The recessed part 212 has another end that is positioned to be opposed to the through hole H1 of the wiring board 10, when the lower mold 210 is stacked on the wiring board 10.

In the present modification example, the upper mold 220 has, for example, the recessed part 221, as illustrated in Parts (A), (B), and (C) of FIG. 23. The recessed part 221 is a single, continuous part that is positioned to be opposed to the covering target region, when the upper mold 220 is stacked on the wiring board 10. The covering target region is a single, continuous region that is a part of the first major surface 11 and includes the electronic components 20.

The recessed part 221 has a three-dimensional shape corresponding to the shape of the part of the resin part 30 on the first major surface 11 side and the shape of the part of the resin part 30 on the side of the side surface of the wiring board 10. The recessed part 221 has one end that is positioned at a part not to be opposed to the wiring board 10, when the upper mold 220 is stacked on the wiring board 10. The above-described part not to be opposed to the wiring board 10 is hereinafter referred to as a "non-opposed part". The recessed part 221 has another end that is the end part 223. The end part 223 is positioned to be opposed to the non-mounting region S4, of the first major surface 11, on which the electronic components 20 are not mounted, when the upper mold 220 is stacked on the wiring board 10. The end part 223 is positioned farthest from the above-described non-opposed part, along the outline of the recessed part 221. For example, a part, of the recessed part 221, between the above-described non-opposed part and the end part 223 may have a band shape that extends from the above-described non-opposed part to the end part 223 as illustrated in Part (A) of FIG. 23, or may have a non-band shape that has different widths in different portions.

As illustrated in Part (C) of FIG. 23, the end part 223 has, for example, the part, i.e., the second part 223B, having the thickness that is greater than the thickness of the adjacent part 224. The adjacent part 224 is a part, of the recessed part 221, that is adjacent to the end part 223. The end part 223 further has, for example, the shape in which the thickness of the end part 223 increases with an increase in distance from the adjacent part 224, as illustrated in Part (C) of FIG. 23. The end part 223 has the shape in which the thickness of the end part 223 increases with an increase in distance from the adjacent part 224, at the part, i.e., the first part 223A, between the adjacent part 224 and the second part 223B.

In the present modification example, in the manufacturing process, the uncured resin 300 is injected into the gate part 213 of the lower mold 210, thereby feeding the uncured resin 300 into the recessed part 212 via the gate part 213. In this case, the uncured resin 300 in the recessed part 212 is fed into the recessed part 221 of the upper mold 220 via the above-described non-opposed part.

In the process in which the uncured resin 300 is fed into the recessed parts 212 and 221, air bubbles can be generated in the uncured resin 300 due to the three-dimensional structure of the electronic components 20 disposed in the recessed parts 212 and 221. When air bubbles are generated in the uncured resin 300, the air bubbles in the uncured resin 300 move toward the end part 223 and are eventually accumulated at the end part 223, i.e., a flow end. In the end part 223, a pressure on the uncured resin 300 can sometimes increase locally. In such a case, the uncured resin 300 can leak out of the end part 223. Note that in the process in which the uncured resin 300 is fed into the recessed parts 212 and 221, a gas remaining in the recessed parts 212 and 221 or a gas generated in the recessed parts 212 and 221 is, for example, discharged to the outside through the vent of the upper mold 220.

In the present modification example, the resin part 33 includes a part in contact with the first major surface 11, a part in contact with the second major surface 12, and a part, i.e., the coupling part 34, in contact with the side surface of the wiring board 10. In such a case, air bubbles are generated more easily in the uncured resin 300, as compared with the case of the above-described embodiment. However, the part of the resin part 33 in contact with the first major surface 11 has the end part 33 in contact with the non-mounting region S4. This makes it possible to concentrate, in the end part 33, voids and burrs to be generated in the resin part 33 in the manufacturing process. Because the electronic components 20 are not present in the end part 33, there is a very low possibility that, for example, moisture in the atmospheric air reaches the electronic components 20 via a void or a burr in the end part 33. Therefore, it is possible to suppress a decrease in the waterproof property caused by a burr or a void.

### Modification Example G

In Modification example F described above, as illustrated in FIGS. 24, 25, and 26, the wiring board 10 may have, for example, the through hole H1. As illustrated in FIG. 26, the resin part 30 includes, for example, the part in contact with the first major surface 11, the part in contact with the second major surface 12, the coupling part 34, and a part filling the through hole H1. The part, of the resin part 30, that fills the through hole H1 corresponds to a specific example of a "fourth resin part" in an embodiment of the present technology. FIG. 24 illustrates a modification example of the plan configuration of the surface, of the circuit board 100, on the first major surface 11 side. FIG. 25 illustrates a plan configuration example of the surface, of the circuit board 100, on the second major surface 12 side. FIG. 26 illustrates a sectional configuration example of the circuit board 100 illustrated in FIGS. 24 and 25, taken along line A-A. In such a case, it is possible to feed the uncured resin 300 into the end part 223 with a lower pressure in the manufacturing process.

When the wiring board 10 has the through hole H1, air bubbles are generated more easily in the uncured resin 300, as compared with the case of Modification example F described above. However, the part, of the resin part 33, in contact with the first major surface 11 has the end part 33 in contact with the non-mounting region S4. This makes it possible to concentrate, in the end part 33, voids and burrs to be generated in the resin part 33 in the manufacturing process. Because the electronic components 20 are not present in the end part 33, there is a very low possibility that, for example, moisture in the atmospheric air reaches the electronic components 20 via a void or a burr in the end part 33. Therefore, it is possible to suppress a decrease in the waterproof property caused by a burr or a void.

FIG. 27 illustrates a perspective configuration example of a battery pack 1000 including the circuit board 100 according to any of the example embodiment and Modification examples A to F described above (hereinafter, simply referred to as the "circuit board 100"). FIG. 28 illustrates a perspective configuration example of a battery module 300 and the circuit board 100 that are contents of the battery pack 1000. FIG. 29 illustrates an exploded perspective configuration example of the battery pack 1000.

As illustrated in FIGS. 27 and 28, the battery pack 1000 includes, for example, an outer casing 400, the battery module 300, and the circuit board 100. The battery module 300 and the circuit board 100 are housed in the outer casing 400. The battery module 300 includes, for example, one or more batteries 310, a plurality of battery holders 320, and a plurality of metal tabs 330, as illustrated in FIG. 29. The circuit board 100 is coupled to, for example, the metal tabs 330, and serves as a control board that controls charging and discharging of the one or more batteries 310. The circuit board 100 may include, for example, a circuit for a task such as measuring a voltage of the one or more batteries 310, detecting a remaining capacity of the one or more batteries 310, or detecting whether there is an overcurrent by measuring a current outputted from the one or more batteries 310.

The outer casing 400 includes, for example, a lower casing 420 and an upper casing 430, as illustrated in FIG. 29. The lower casing 420 and the upper casing 430 are stacked on each other to form a housing space for housing the battery module 300 and the circuit board 100. The outer casing 400, e.g., the lower casing 420, is provided with an external terminal 410 coupled to the circuit board 100. The battery module 300 is coupled to the external terminal 410 via the circuit board 100.

In the present application example, the circuit board 100 according to any of the example embodiment and Modification examples A to F described above is used for the battery pack 1000. This makes it possible to prevent deterioration of the electronic components 20 of the circuit board 100 due to, for example, moisture in the atmospheric air. It is therefore possible to provide the battery pack 1000 having high resistance to, for example, moisture in the atmospheric air.

Although the present technology has been described hereinabove with reference to some embodiments, the present technology is not limited to the examples described in the above-described embodiments, and various modifications can be made to the present technology. The effects described herein are mere examples, and effects of the present technology are therefore not limited to those described herein. Accordingly, the present technology may achieve any other effect.

Note that the present technology may have any of the following configurations according to an embodiment.

<1>

A circuit board including:

a wiring board including a first major surface;

a plurality of first electronic components mounted on the first major surface; and

a first resin part that is a single, continuous part provided in contact with only a part of the first major surface and covering the first electronic components, in which

the first major surface includes a covered region and an uncovered region, the covered region being a single, continuous region covered with the first resin part, the uncovered region not being covered with the first resin part, and

the first resin part includes an end part in contact with a non-mounting region, of the first major surface, on which the first electronic components are not mounted.

<2>

The circuit board according to <1>, in which the end part is positioned to be spaced away from an edge of the wiring board, and has three sides surrounded by the uncovered region.

<3>

The circuit board according to <1> or <2>, in which

the first resin part includes a gate part in contact with an edge of the wiring board, and

the end part is positioned farthest from the gate part, along an outline of the first resin part.

<4>

The circuit board according to any one of <1> to <3>, in which the end part has a width greater than a width of an adjacent part of the first resin part, the adjacent part being adjacent to the end part.

<5>

The circuit board according to <4>, in which the end part has a tapered shape having a width that increases with an increase in distance from the adjacent part.

<6>

The circuit board according to <4> or <5>, in which the end part has a part having a thickness that is greater than a thickness of the adjacent part.

<7>

The circuit board according to <6>, in which the end part has a shape in which a thickness of the end part increases with an increase in distance from the adjacent part.

<8>

The circuit board according to <6> or <7>, in which the end part has a part, close to the adjacent part, in which a thickness of the end part is smaller than the thickness of the adjacent part.

<9>

The circuit board according to any one of <4> to <8>, in which the end part has a polygonal shape similar to a circular shape or an elliptical shape in a plan view.

<10>

The circuit board according to any one of <4> to <8>, in which the end part has a circular shape or an elliptical shape in a plan view.

<11>

The circuit board according to any one of <1> to <10>, in which the end part includes at least one resin material selected from the group consisting of polyamide, polyester, and polyurethane.

<12>

The circuit board according to any one of <1> to <11>, further including:

a plurality of second electronic components mounted on a second major surface opposed to the first major surface;

a second resin part that is a single, continuous part provided in contact with only a part of the second major surface and covering the second electronic components; and

a third resin part that is in contact with a side surface of the wiring board and is coupled to the first resin part and the second resin part.

<13>

The circuit board according to <12>, in which

the wiring board has a through hole, and

the circuit board further includes a fourth resin part that fills the through hole and is coupled to the first resin part and the second resin part.

<14>

A battery pack including the circuit board according to any one of <1> to <13> as a circuit board that controls charging and discharging of one or more batteries.

<15>

A method of manufacturing a circuit board including a wiring board including a first major surface, a plurality of electronic components mounted on the first major surface, and a resin part that is a single, continuous part provided in contact with only a part of the first major surface and covering the electronic components, the method including:

stacking a mold including a recessed part, on the wiring board, and feeding an uncured resin into the recessed part, the wiring board including the first major surface on which the electronic components are mounted, the recessed part being a single, continuous part positioned to be opposed to a covering target region, the covering target region being a single, continuous region that is a part of the first major surface and includes the electronic components;

forming the resin part by cooling and solidifying, in the mold, the uncured resin fed into the recessed part; and

removing the mold from the wiring board, in which

the recessed part has an end part that is positioned to be opposed to a non-mounting region, of the first major surface, on which the electronic components are not mounted, when the mold is stacked on the wiring board.

<16>

The method of manufacturing the circuit board according to <15>, in which

the mold includes a gate part coupled to the recessed part, and

the end part is positioned farthest from the gate part, along an outline of the recessed part.

<17>

The method of manufacturing the circuit board according to <15> or <16>, in which the end part has a width greater than a width of an adjacent part of the recessed part, the adjacent part being adjacent to the end part.

<18>

The method of manufacturing the circuit board according to <17>, in which the end part has a tapered shape having a width that increases with an increase in distance from the adjacent part.

<19>

The method of manufacturing the circuit board according to <17>, in which the end part includes a part having a thickness that is greater than a thickness of the adjacent part.

<20>

The method of manufacturing the circuit board according to <19>, in which the end part has a shape in which a thickness of the end part increases with an increase in distance from the adjacent part.

<21>

The method of manufacturing the circuit board according to any one of <17> to <20>, in which the end part has a polygonal shape similar to a circular shape or an elliptical shape in a plan view.

<22>

The method of manufacturing the circuit board according to any one of <17> to <20>, in which the end part has a circular shape or an elliptical shape in a plan view.

It should be understood that various changes and modifications to the embodiments described herein will be apparent to those skilled in the art. Such changes and modifications can be made without departing from the spirit and scope of the present subject matter and without diminishing its intended advantages. It is therefore intended that such changes and modifications be covered by the appended claims.

1. A circuit board comprising:
a wiring board including a first major surface;
a plurality of first electronic components mounted on the first major surface; and
a first resin part that is a single, continuous part provided in contact with only a part of the first major surface and covering the first electronic components, wherein
the first major surface includes a covered region and an uncovered region, the covered region being a single, continuous region covered with the first resin part, the uncovered region not being covered with the first resin part, and
the first resin part includes an end part in contact with a non-mounting region, of the first major surface, on which the first electronic components are not mounted.

2. The circuit board according to claim 1, wherein the end part is positioned to be spaced away from an edge of the wiring board, and has three sides surrounded by the uncovered region.

3. The circuit board according to claim 1, wherein
the first resin part includes a gate part in contact with an edge of the wiring board, and
the end part is positioned farthest from the gate part, along an outline of the first resin part.

4. The circuit board according to claim 1, wherein the end part has a width greater than a width of an adjacent part of the first resin part, the adjacent part being adjacent to the end part.

5. The circuit board according to claim 4, wherein the end part has a tapered shape having a width that increases with an increase in distance from the adjacent part.

6. The circuit board according to claim 4, wherein the end part has a part having a thickness that is greater than a thickness of the adjacent part.

7. The circuit board according to claim 6, wherein the end part has a shape in which a thickness of the end part increases with an increase in distance from the adjacent part.

8. The circuit board according to claim 6, wherein the end part has a part, close to the adjacent part, in which a thickness of the end part is smaller than the thickness of the adjacent part.

9. The circuit board according to claim 4, wherein the end part has a polygonal shape similar to a circular shape or an elliptical shape in a plan view.

10. The circuit board according to claim 4, wherein the end part has a circular shape or an elliptical shape in a plan view.

11. The circuit board according to claim 1, wherein the end part includes at least one resin material selected from the group consisting of polyamide, polyester, and polyurethane.

12. The circuit board according to claim 1, further comprising:
a plurality of second electronic components mounted on a second major surface opposed to the first major surface;
a second resin part that is a single, continuous part provided in contact with only a part of the second major surface and covering the second electronic components; and
a third resin part that is in contact with a side surface of the wiring board and is coupled to the first resin part and the second resin part.

13. The circuit board according to claim 12, wherein
the wiring board has a through hole, and
the circuit board further comprises a fourth resin part that fills the through hole and is coupled to the first resin part and the second resin part.

14. A battery pack comprising the circuit board according to claim 1, wherein the circuit board is configured to control charging and discharging of one or more batteries.

15. A method of manufacturing a circuit board including a wiring board including a first major surface, a plurality of electronic components mounted on the first major surface, and a resin part that is a single, continuous part provided in contact with only a part of the first major surface and covering the electronic components, the method comprising:
stacking a mold including a recessed part, on the wiring board, and feeding an uncured resin into the recessed part, the wiring board including the first major surface on which the electronic components are mounted, the recessed part being a single, continuous part positioned to be opposed to a covering target region, the covering target region being a single, continuous region that is a part of the first major surface and includes the electronic components;
forming the resin part by cooling and solidifying, in the mold, the uncured resin fed into the recessed part; and
removing the mold from the wiring board, wherein
the recessed part has an end part that is positioned to be opposed to a non-mounting region, of the first major surface, on which the electronic components are not mounted, when the mold is stacked on the wiring board.
